(19) United States
(12) Patent Application Publication
(10) Pub. No.: US 2011/0307748 A1
(43) Pub. Date: Dec. 15, 2011

(54) TECHNIQUES FOR ERROR DIAGNOSIS IN VLSI SYSTEMS

(75) Inventor: Michael Laisne, Encinitas, CA (US)

(73) Assignee: QUALCOMM INCORPORATED, San Diego, CA (US)

(21) Appl. No.: 13/160,423

(22) Filed: Jun. 14, 2011

Related U.S. Application Data
(60) Provisional application No. 61/355,032, filed on Jun. 15, 2010.

(51) Int. Cl. G01R 31/3177; G06F 11/25

(52) U.S. Cl. 714/726; 714/735; 714/E11.155

(57) ABSTRACT

Techniques for designing and storing test input and output data vectors to diagnose bit errors in a testing sequence. In an aspect, test input vectors may be chosen such that the corresponding correct output vectors form codewords of a forward error-correcting code. In another aspect, the correct test output vectors may be compressed to reduce the memory requirements of the testing system. In yet another aspect, test input vectors may be sorted such that the test output vectors are monotonically increasing or decreasing in sequence, and corresponding delta's between output vectors in the sequence may be stored to reduce the memory requirements. Further aspects provide for storing information relating to the correct output vectors in various efficient formats, including storing base value-referenced offsets, and storing relative operations and output vector segments to allow derivation of correct output vectors from memory when required.

### CLAIM OF PRIORITY UNDER 35 U.S.C. §119

The present Application for Patent claims priority to Provisional Application No. 61/355,032 entitled “BYPASS FOR ATPG DIAGNOSTICS” filed Jun. 15, 2010, and assigned to the assignee hereof and hereby expressly/incorporated by reference herein.

### BACKGROUND

1. Field

The disclosure relates to techniques for efficiently processing and storing information to diagnose errors occurring in VLSI systems.

2. Background

Semiconductor chips such as very-large scale integrated (VLSI) circuits typically have a large number of circuit components. For example, thousands of flip-flops may be arranged logically in rows and columns, with logic circuits disposed between the columns, connecting flip-flops in corresponding rows between adjacent columns. With so many components, faulty circuits are inevitable and are checked for during manufacture of the chips, using, e.g., automatic test pattern generation (ATPG) to generate test vectors. Due to the large number of components, obtaining output data from each flip-flop or logic circuit is impractical as the amount of data would be difficult or impossible to store and analyze. To reduce the amount of data to a more manageable quantity, the outputs of the components and circuitry may be compressed using compression logic (e.g., XOR trees) to produce a reduced data output that is checked for indications of errors.

A trade-off to using compression logic to reduce the amount of data is that the granularity of error isolation is also reduced, so that when analyzing compressed test results, it may not be possible to identify the precise flip-flop where the erroneous data was captured. To improve yield, significantly more automatic test equipment (ATE) memory would be needed to perform the required diagnosis. It would be desirable to provide efficient techniques to store and manage the output data generated by testing VLSI systems, while also retaining the granularity needed to precisely identify the flip-flops where the errors occur.

### SUMMARY

An aspect of the present disclosure provides a method comprising: loading a circuitry to be tested with a test input vector; executing a capture cycle on the circuitry to be tested to generate an actual output vector corresponding to the test input vector; and analyzing said actual output vector to determine the identity of at least one erroneous bit in the actual output vector.

Another aspect of the present disclosure provides an apparatus comprising: a scan-in memory configured to store a test input vector to be loaded into a circuitry to be tested; and a scan-out memory configured to store an actual output vector corresponding to the test input vector, the actual output vector generated by the circuitry to be tested after executing a capture cycle on the test input vector; the apparatus configured to analyze the actual output vector stored in the scan-out memory to determine the identity of at least one erroneous bit in the actual output vector.

Yet another aspect of the present disclosure provides an apparatus comprising: means for loading a circuitry to be tested with a test input vector; and means for analyzing an actual output vector of the circuitry to be tested to determine the identity of at least one erroneous bit in the actual output vector.

Yet another aspect of the present disclosure provides a computer program product storing code for causing a computer to perform tests on a circuitry to be tested, the code comprising: code for causing a computer to load a circuitry to be tested with a test input vector; code for causing a computer to execute a capture cycle on the circuitry to be tested to generate an actual output vector corresponding to the test input vector; and code for causing a computer to analyze said actual output vector to determine the identity of at least one erroneous bit in the actual output vector.

### BRIEF DESCRIPTION OF DRAWINGS

FIG. 1 illustrates an exemplary test system architecture 1 according to the present disclosure.

FIG. 2 illustrates an exemplary embodiment of the circuitry 4 and compression logic 6 referred to in FIG. 1.

FIG. 3 illustrates an exemplary embodiment of a method 300 according to the present disclosure.

FIG. 4 shows an exemplary assignment of categories and labels to the flip-flops 14_{1,1} through 14_{4,3} shown in FIG. 2.

FIG. 4A shows a sample vector of (correct) output bits generated according to a test input vector, i.e., bits present in the flip-flops A-M after a “capture cycle” has been executed.

FIG. 5 shows a sample output vector generated according to the same test input vector as used in FIG. 4A, wherein one of the outputs in FIG. 5 is instead in error.

FIG. 6 illustrates an exemplary labeling scheme for the flip-flops 14_{1,1} through 14_{4,3} shown in FIG. 2.

FIG. 7A illustrates an exemplary sequence of test input vectors and un-sorted output vectors, along with corresponding generalized output bit values.

FIG. 7B illustrates an exemplary sequence of test input vectors and sorted output vectors.

FIGS. 8 and 8A illustrate an exemplary method 800 for using the sorting technique to identify bit errors in test output vectors according to the present disclosure.

FIGS. 9 and 9A illustrate an exemplary method 900 for implementing the compression technique.

FIG. 10 illustrates an exemplary embodiment of data compression of the correct output vector bits according to the present disclosure.

FIG. 11 illustrates an “offset” technique according to the present disclosure.

FIG. 12 illustrates a “relative operation” technique according to the present disclosure.

FIG. 13 illustrates a “derivation” technique according to the present disclosure.

FIG. 14 illustrates an exemplary instance of circuitry to be tested 1410, wherein certain flip-flops are missing from rectangular array.

FIG. 15 illustrates an exemplary scheme for labeling the flip-flops shown in FIG. 14.

FIG. 16 illustrates a test input vector sequence 1600 (ABC′D E′F′G′H′J′K′L′M′) stored in the scan-in memory.

FIG. 17 illustrates an exemplary embodiment of a method according to the present disclosure.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

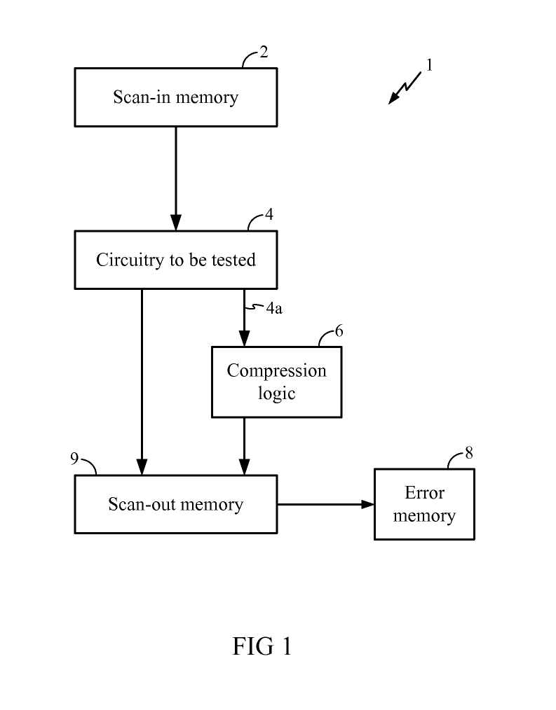

FIG. 1 illustrates an exemplary test system architecture 1 according to the present disclosure. Note the system 1 is shown for illustrative purposes only, and is not meant to limit the scope of the present disclosure to any particular embodiment shown. In FIG. 1, a scan-in memory 2 stores a plurality of input test sequences, or test vectors for testing the functionality of circuitry 4. The circuitry 4 processes the input test vectors from memory 2, and in response generates output data 4a. The circuitry 4 may comprise, e.g., a VLSI system, or any other type of system containing a sizeable number of internal elements to be tested.

When the system 1 operates to test circuitry 4 over a wide range of test conditions, the amount of such generated output data may be voluminous, and thus it may be desirable to compress the information in such output data. The compression logic block 6 may perform this function. The compression logic block 6 may then store information relating to test results in a scan out memory 9. In certain instances, the compression logic block 6 may include, e.g., XOR trees, or other types of logic known in the art.

Note in addition to (or instead of) providing the generated output data to compression logic block 6, the circuitry 4 may provide raw output data to a scan-out memory 9. The output data stored in the scan-out memory 9 may be used for, e.g., diagnostic purposes to accurately determine the identity of faulty elements or blocks in circuitry 4. The scan out memory 9 is compared with the response from either 4 or 6, and the errors are stored in the error memory 8.

In an exemplary embodiment, the scan-in memory 2 and scan-out memory 9 may be provided on a platform commonly known as an automatic test equipment (ATE), or otherwise on any system for testing circuitry known or otherwise derivable by one of ordinary skill in the art. Note while compression logic 6 may be provided on the circuitry 4, it will be appreciated that adopting the techniques described herein may facilitate additional features such as providing the compression logic 6 on the ATE.

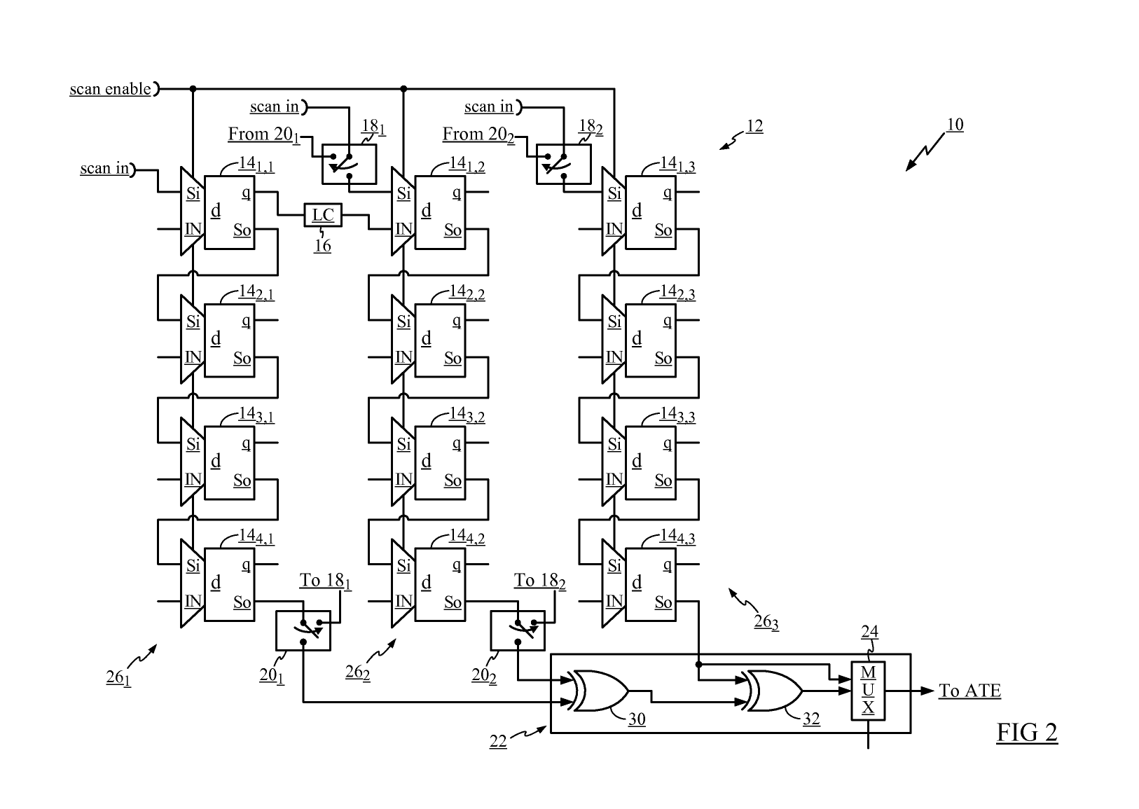

FIG. 2 illustrates an exemplary embodiment of the circuitry 4 and compressor 6 referred to in FIG. 1. While circuitry 4 is shown as including a semiconductor chip 10 in FIG. 2, it will be appreciated that alternative exemplary embodiments may include other circuitry besides a chip 10, e.g., multiple chips, printed circuit boards with discrete components, etc., and thus the illustration of FIG. 2 is not meant to restrict the scope of the present disclosure. Furthermore, while the chip 10 is shown as including flip-flops in FIG. 2, other types of circuitry may also be readily tested using the techniques of the present disclosure, e.g., circuitry containing other types of registers or other memory elements. Such alternative exemplary embodiments are contemplated to be within the scope of the present disclosure.

Referring to FIG. 2, a semiconductor chip 10 includes an array 12 of flip-flops 14, logic circuits 16 (only one logic circuit is shown in FIG. 2), scan-in switches 18, scan-out switches 20, a compression circuit 22, and a multiplexer (MUX) 24 (only one MUX is shown in FIG. 2) connected to automatic test equipment (ATE) located off chip. The flip-flops 14 are arranged in chains 26. The flip-flops 14 in the chain are D flip-flops with standard d inputs and q outputs. The d-input of each flip-flop is coupled to a multiplexer that selects the d-input from either the Si input or the IN input based on the scan enable signal. It will be appreciated that, during normal operation, the scan enable signal may be in a first state to select the IN input as the d-input, while during testing, the scan enable signal may be in a second state to select the Si input as the d-input.

The So output of the flip-flop may behave identically to the Q output, storing the Si values at the corresponding d-input at each triggering edge of a clock signal if scan enable is set. It will be appreciated that various additional instances of logic circuits 16 (only one instance of which is shown in FIG. 2) may be present, coupling the q output of any flip-flop with the d input of another other flip-flop.

During testing, a test vector is loaded from the scan-in memory into the flip-flops 14 by connecting a respective scan-in line to the Si of each scan chain. The data on the scan-in line can be directly from the ATE, through a decompressor, from a pseudorandom pattern generator (PRPG), or derived in other ways, with the input state to the flip-flops 14 being known or derivable. The Si's and So's of each flip-flop 14 may be daisy-chain connected such that at each triggering edge (or level in the case of level-sensitive scan design, or LSSD) of a clock cycle, the So's take the values of the corresponding Si's in each flip-flop 14. With the test vector loaded, a “capture cycle” is run where the present value at Si is transferred to the q output of each gate and applied to the logic circuitry 16 between the q and d ports. The data is captured into the flip-flop 14 from the d input and stored in the flip-flop 14 at the next clock edge. The data are then scanned out through the flip-flops 14, daisy chained from Si to So. The data comes out on each scan chain's 26 respective scan-out line. The data pass through the compressor 22 and the outputs of the chip 10 are provided to the ATE (or other test equipment) that checks for errors. Where the output deviates from the expected value, at least one error is known to exist in the flip-flops 14 at the corresponding level (row) in the flip-flops 14.

Note while the compressor 22 is shown in FIG. 2 as including two XOR-gates 30, 32 with one output, it will be appreciated that a compressor may be implemented using any logic known in the art, any number of XOR gates, any number of outputs less than the number of such scan chains, and such alternative exemplary embodiments are contemplated to be within the scope of the present disclosure.

When an error is detected in the chip outputs, then the same test input conditions may be reloaded into the flip-flops 14 as before.

With the stimulus data from the failure reloaded into the scan chains, a capture cycle is executed. The capture cycle applies the test data to the logic circuits 16 and stores the resulting data in the corresponding d inputs as discussed above. The data is captured into the flip-flop 14 from the d input and stored in the flip-flop 14 with the next clock edge, again as before.

With the test results captured, the chains are then configured, using muxes 18, 20, and 24, such that the number of chains is equivalent to the number of available outputs or less. The chain and configuration may be selected based on the chains known to be involved in the failure. The compression circuitry 22 is bypassed and the failing data are shifted out to the ATE. The switches 18, 20 are changed from their compression states/modes shown in FIG. 2 to their bypass states/modes. In their bypass states, the switches 18, 20 connect the chains 26 in series, with the So port of the last flip-flop, here 14_{4,x}, in each chain 26ₙ being connected to the Si port of the first flip-flop, 14_{1,x}, in the next chain 26ₙ₊₁. The So port of the last flip-flop, here 14_{4,3}, of the last chain, here 26₃, is connected to the compression circuit 22 and to the MUX 24. Note the control for the MUX may come from the test controller, e.g., TAP, ATE, etc. The MUX connects the compression circuit 22 to the ATE in the compression state/mode and connects the So port of the last flip-flop, here 14_{4,3}, in the array 12 to the ATE in the bypass state/mode.

While a specific implementation of circuitry for alternately switching between normal and test operation for a plurality of flip-flops has been described, one of ordinary skill in the art would appreciate that other implementations of such circuitry are possible. For example, alternative test platforms may provide separate shift registers and/or other memory components to store intermediate values present in the circuitry, to be subsequently processed. Such alternative exemplary embodiments are contemplated to be within the scope of the present disclosure.

The ATE analyzes the data from the compression mode and the bypass mode to determine the chain 26 of the failing flip-flop(s) 14. Combined with the knowledge of the level of the failure(s) derived from the compressed output, the location of the failing flip-flop(s) 14 can be determined. One way of analyzing the data is for the ATE to apply error detection techniques further described hereinbelow using the compressed and the uncompressed outputs to isolate the flip-flop where each error occurred. The flip-flop 14 identified by this analysis is the flip-flop 14 that contained the erroneous data.

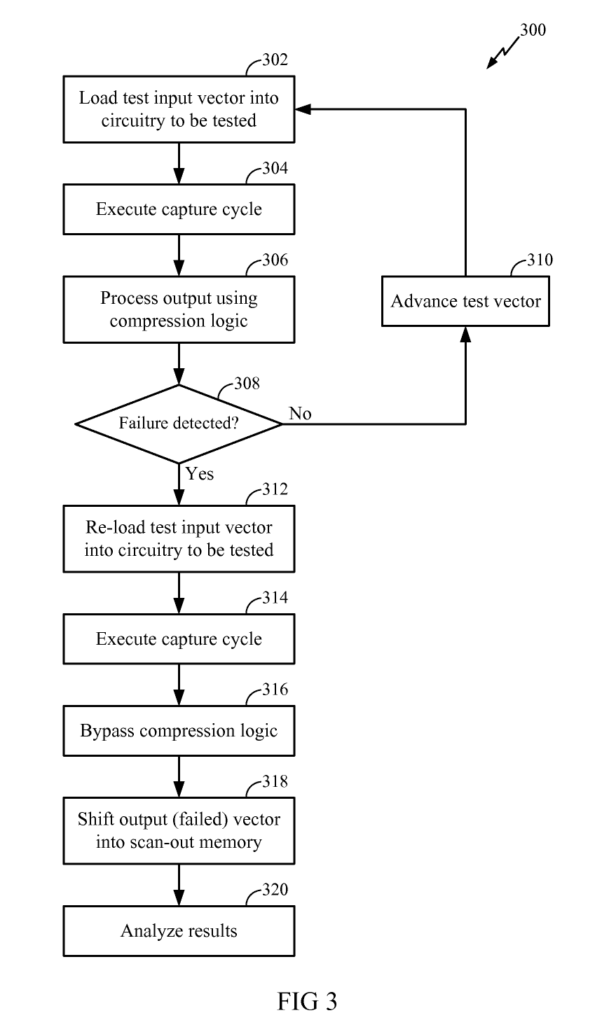

FIG. 3 illustrates an exemplary embodiment of a method 300 according to the present disclosure. Note the method 300 is shown for illustrative purposes only, and is not meant to limit the scope of the present disclosure to any particular method shown.

In FIG. 3, at block 302, a test input vector is loaded into circuitry to be tested. In an exemplary embodiment, the test input vector may be loaded from the scan-in memory 2 as shown in FIG. 1, and the circuitry to be tested may correspond to circuitry 4 in FIG. 1, and may further correspond to, e.g., semiconductor chip 10 in FIG. 2.

At block 304, after the test input vector is loaded, a capture cycle is executed by the circuitry 4. It will be appreciated that a capture cycle may correspond to one or more clock cycles of the circuitry 4 in operation, wherein the test input vector loaded at block 302 is caused to be processed by the circuitry 4 for the duration of the capture cycle.

At block 306, the output of circuitry 4 after the capture cycle is processed using compression logic. In an exemplary embodiment, the compression logic may correspond to, e.g., compression logic block 6 in FIG. 1.

At block 308, it is checked whether a failure is detected in the output of circuitry 4. In an exemplary embodiment, the checking may be performed by assessing an output of the compression logic block 6 in FIG. 1. Alternatively, the checking may be performed in any manner known to one of ordinary skill in the art.

If no failure is detected, the method proceeds to block 310, where the next test vector may be loaded (i.e., the test vector is advanced), and the method returns to block 302. In practice, the test vector may be loaded into the scan chains 26 as the results are loaded into the scan-out memory 9.

If a failure is detected, the method proceeds to block 312. At block 312, the test input vector causing the detected failure may be re-loaded into the circuitry to be tested, e.g., from the scan-in memory 2.

At block 314, the capture cycle is again executed.

At block 316, the compression logic 316 is bypassed, as the compression logic 316 has previously served its purpose of identifying the presence of an error (but not the specific identity of the error within the circuitry).

At block 318, the output vector of the circuitry containing the failure is provided to the scan-out memory, e.g., memory 9 in FIG. 1.

At block 320, the output data in the scan-out memory is analyzed to identify which particular circuit elements or blocks caused the errors in the test results. In an exemplary embodiment, the techniques used to perform such analysis may be as described hereinbelow with reference to the techniques of parity, sorting, compression, encoding, offset, fixed value, table look up, derivation, and/or any combination of such techniques.

In an exemplary embodiment, a “parity” technique may be used to determine the identities of erroneous bits. According to the parity technique, the test input vectors in scan-in memory 2 are pre-selected such that the output data, i.e., post-capture cycle output data generated by the circuitry to be tested, have bit values specifically corresponding to the bits of one or more forward-error correcting (FEC) codewords, when no faults are present in the circuitry. In other words, by selecting test conditions according to this parity criterion, the correct output data generated by the circuitry to be tested will only correspond to valid codewords of an FEC code. On the other hand, when one or more faults are present in the circuitry, then the output data generated by the circuitry to be tested will generally not correspond to a valid codeword in the FEC code. In this case, due to the properties of the FEC code, the original (correct) FEC codeword may nevertheless be recovered by decoding the incorrect output data, and comparing the correct and incorrect bit sequences to each other to identify the erroneous bit(s).

An example of the parity technique will be described hereinbelow, wherein the FEC code is a “Hamming” code well-known in the art. One of ordinary skill in the art will nevertheless appreciate that other types of codes besides Hamming codes may readily be applied in view of the present disclosure, and such alternative techniques are contemplated to fall within the scope of the present disclosure.

According to the parity technique, each of a set of flip-flops within the circuitry to be tested is assigned both a category and a label. The categories assigned include a “care bit” category and a “don't care bit” category. Bits assigned to a “care bit” category include bits associated with flip-flops that contain the test results from logic circuits whose functionality is desired to be tested for the given test input vector. For example, assume there are a total number X of flip-flops and associated logic circuits in one portion of a circuit. The X total bits may correspond, e.g., to the X output bits coupled to the compression logic circuitry 8. Any specific test input vector may be designed to only test the functionality of logic circuits driving some subset Y of the total X flip-flops. The bits associated with this subset Y may thus be assigned to the “care bit” category, while all other bits may be assigned to the “don't care bit” category.

Once each bit is categorized as described above, a label may further be assigned to each bit (including both care bits and don't care bits). In an exemplary embodiment, each bit is assigned to a distinct integer label selected from the set of X consecutive positive integers starting with 1. The assignment of integers to bits may be made according to the following conditions: 1) integer powers of 2 are exclusively assigned to don't care bits, and such bits will also be referred to as “parity bits;” and 2) all other integers may be arbitrarily assigned to care bits, and such bits will be referred to as “data bits.” In an exemplary embodiment, care bits must be assigned as “data bits,” while don't care bits may be assigned as “parity bits” or “data bits,” or may remain unassigned if additional “parity bits” are not required.

Note that, alternatively, the parity and other information for the techniques discussed can be stored in the don't care bits of the scan-input memory. The don't care bits of the scan-input memory are those bits that are required as inputs for the targeted tests. The remaining bits may be filled by the ATPG tool with random data.

According to the parity technique, a care bit must be a data bit, and a parity bit must be a don't care bit (although it could be a care bit with some minor loss of resolution). The remaining don't care bits can be either data bits or care bits. Note that in Hamming parity coding parity bits are sparse, and in ATPG test generation care bits are sparse. Thus, there may likely be an excess of data bits and don't care bits. This means that the algorithm can be tailored to select don't care bits as parity bits that are simple to test and control and less likely to fail because they have fewer elements.

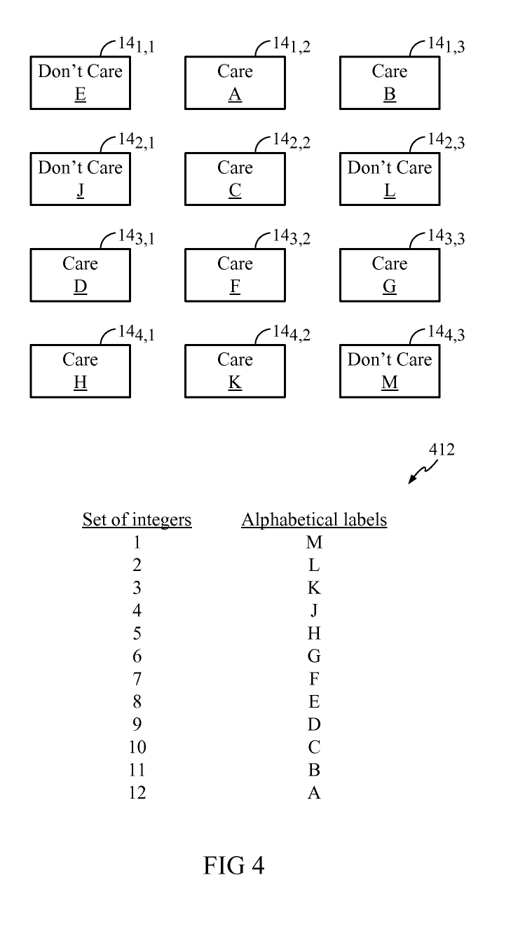

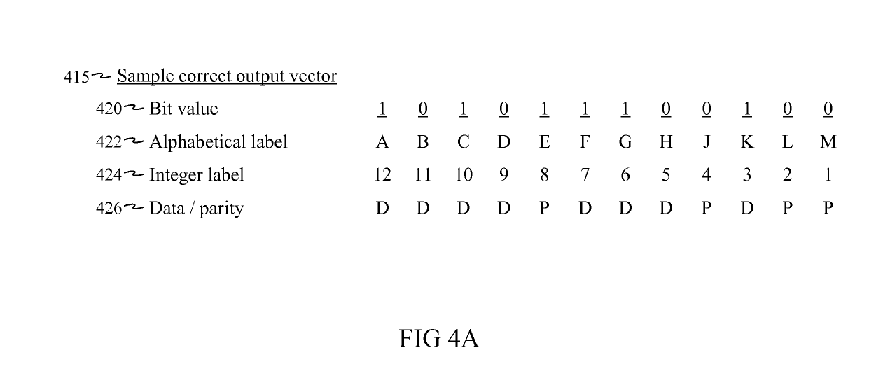

FIG. 4 shows an exemplary assignment of categories and labels to the flip-flops 14_{1,1} through 14_{4,3} shown in FIG. 2. It will be appreciated that FIG. 4 is shown for illustrative purposes only, and is not meant to limit the scope of the parity techniques to any particular number or arrangement of flip-flops shown, and one of ordinary skill in the art may readily apply the exemplary disclosed techniques to alternative configurations of flip-flops. Note in FIG. 4, for ease of illustration, the integer label 1 through 12 for each bit is expressed as an equivalent alphabetical letter A through M, with the one-to-one correspondence as shown at 412.

In FIG. 4, for the 12 bits shown, there are four don't care or parity bits assigned to labels M, L, J, and E, and eight care or data bits assigned to labels, A, B, C, D, F, G, H, and K. It will be appreciated as earlier described that the categorization of a bit as a “don't care bit” or a “care bit” is made according to the particular input or output for a given test vector. Within each category, the labels may be arbitrarily assigned to bits, as long as only integer powers of 2 are assigned to don't care bits, and other integers are assigned to care bits. Note generally that while 12 bits are shown for the vector length in FIG. 4 and elsewhere in the present disclosure, it will be appreciated that the techniques may be readily applied to vectors having arbitrary length, and such alternative exemplary embodiments are contemplated to be within the scope of the present disclosure.

Given the above assignment of bits to integer labels, specific codewords according to a Hamming code may be chosen using the following criteria. In particular, Bit 1 covers all the bit positions in which the least significant bit is set (e.g., bit 3 (11), bit 5 (101), bit 7 (111), bit 9 (1001), bit 11 (1011), etc.), Bit 2 covers all the bit positions in which the second least significant bit is set (e.g., bit 3 (11), bit 6 (110), bit 7 (111), bit 10 (1010), bit 11 (1011), bit 14 (1110), etc.), Bit 4 covers all the bit positions in which the third least significant bit is set (e.g., bits 4-7 (100-111), bits 12-15 (1100-1111), bits 20-23 (10100-10111), bits 28-31 (11100-11111), etc.), and Bit 8 covers all the bit positions in which the fourth least significant bit is set (e.g., bits 8-15 (1000-1111), bits 24-31 (11000-11111), bits 40-47 (101000-101111), bits 56-63 (111000-111111), etc.). The parity structure (even, odd, or mixed) can then be selected to most easily match the care bits. Again, this can be done by either selecting controllable circuits or analyzing the captured register states of previously generated ATPG test patterns.

Note the selection of parity structure (even, odd, or mixed) must be known by the test analysis engine, but is otherwise chosen according to what is the most convenient for vector generation and selection. In this case, “even” and “odd parity refers to how the bit is typically set in Hamming code operations. “Mixed” parity refers to the selection of even or odd parity depending on the parity bit and for the convenience of test selection.

FIG. 4A shows a sample vector of (correct) output bits generated according to a test input vector, i.e., bits present in the flip-flops A-M after a “capture cycle” has been executed. In FIG. 4A, the sample output bit values are shown at row 420. The alphabetical labels A-M for the bits are shown in row 422, and corresponding integer labels 1-12 are shown at row 424. Finally, the categorization of each bit as a data bit (i.e., care bit) or parity bit (i.e., don't care bit) is shown at row 426. Note in the correct output vector of FIG. 4A, the series of parity bits M, K, J, and E have values of 0, 0, 0, and 1, respectively.

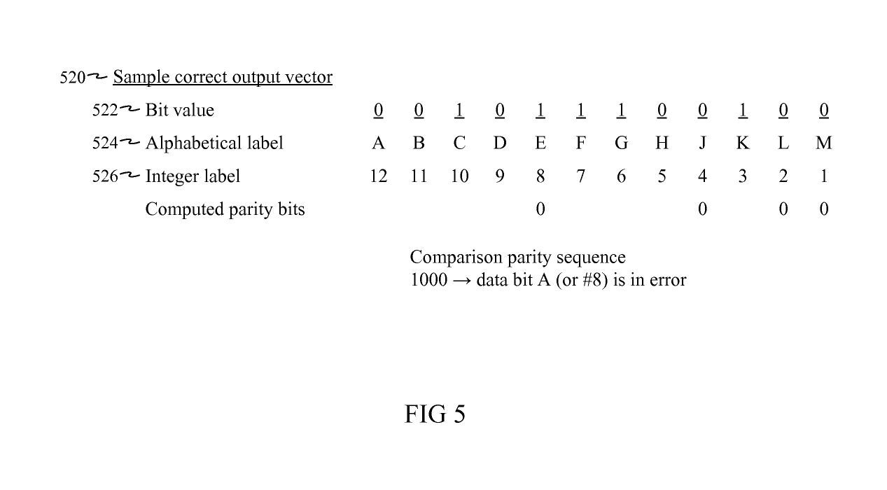

FIG. 5 shows a sample output vector generated according to the same test input vector as used in FIG. 4A, wherein one of the outputs in FIG. 5 is instead in error. For even parity, from the sequence of output bits shown in FIG. 5, the parity bits of the generated output sequence may be calculated as follows:

### M=(B=0) XOR (D=0) XOR (G=1) XOR (K=1)=0;

### L=(B=0) XOR (C=1) XOR (G=1) XOR (H=0)=0;

### J=(B=0) XOR (C=1) XOR (D=0) XOR (F=1)=0; and

### E=(A=0)=0.

Comparing the calculated parity bits of 0, 0, 0, 0 to the actually received parity bits of 0, 0, 0, 1, it will be seen that the E parity bit is different. According to the rules of the Hamming code, this indicates that bit 1000 (8) or A was received in error. For odd parity, the tests would be constructed and the flip-flops labeled such that M, L, J, and E would each equal 1 in the passing case. For mixed parity, the values of M, L, J, and E can be chosen to be either 1 or 0 in the passing case, but their state in the passing case is known by the analysis engine or process. It should also be noted that the parity bits can be stored in other alternative means including but not limited to storage in the tester program, storage in scan-in memory using extra cycles between tests, unused scan-in memory locations, or input don't care bits, or transferred from scan-in memory locations to flip-flops that are unclocked in capture mode (the opposite state of scan enable).

As illustrated with the above example, by choosing test vectors having expected output bits constructed according to a Hamming code, the precise identities of the bits received in error may advantageously be determined without significant memory or computational overhead. It will be appreciated that similar advantages may also be obtained using error-correcting codes other than Hamming codes.

One of ordinary skill in the art will appreciate that the Hamming code techniques described hereinabove may be generally applied to any number of don't care bits by arbitrarily extending the Hamming code. Such alternative exemplary embodiments are contemplated to be within the scope of the present disclosure.

In an alternative exemplary embodiment, it will be appreciated that the parity bits of the output vectors may be separately stored in a memory (including, but not limited to, ATE server memory and scan-in memory), and retrieved when an error is detected in an actual output vector to construct a correct output vector for comparison. Such alternative exemplary embodiments are contemplated to be within the scope of the present disclosure. This technique may be used in combination with any of the other techniques disclosed herein.

In an alternative exemplary embodiment, a “sorting” technique may be used to determine the identities of erroneous bits. According to the sorting technique, test input vectors loaded in scan-in memory 2 are pre-arranged in sequence, such that the resulting output vectors monotonically increase (or decrease) in value according to a predetermined bit assignment. Further according to the sorting technique, the delta values corresponding to the monotonically increasing (or decreasing) output bit sequences are stored in a memory (i.e., the “delta” memory), and may later be retrieved to reconstruct the correct output vector when an error is detected. In this manner, the identity of the erroneous bit may be determined by comparing the erroneous bit sequence with the correct output vector.

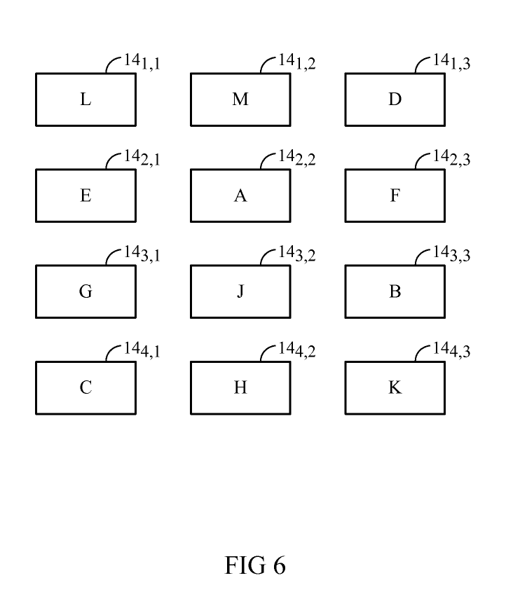

FIG. 6 illustrates an exemplary labeling scheme for the flip-flops 14_{1,1} through 14_{4,3} shown in FIG. 2. According to the sorting technique, the flip-flops may be arbitrarily labeled using integer labels (shown again as alphabetical labels in FIG. 6 for convenience), or labeled subject to the criterion that the flip-flops that switch in bit value most often for a given set of output vectors are preferably labeled with the smallest bit values (e.g., with M being the smallest bit value, or least significant bit LSB in FIG. 6), while the flip-flops that switch in bit value the least often are preferably labeled with the largest bit values (e.g., with A being the largest bit value, or most significant bit MSB in FIG. 6). It will be appreciated that the labeling shown in FIG. 6 is shown for illustrative purposes, and is not meant to limit the scope of the present disclosure to any particular labeling scheme or number of registers.

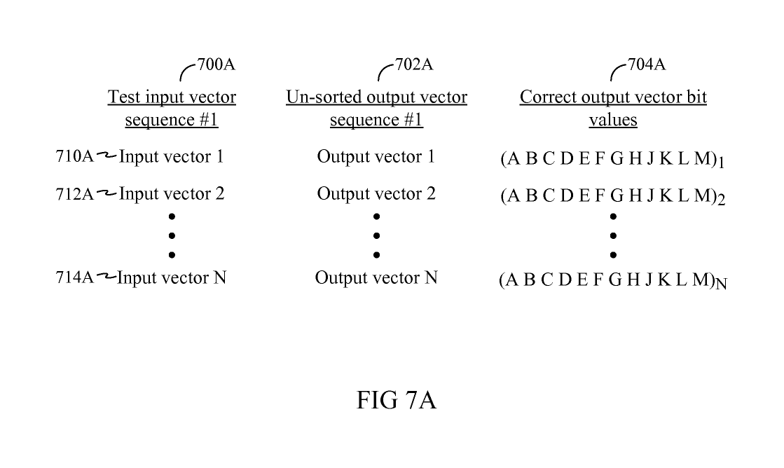

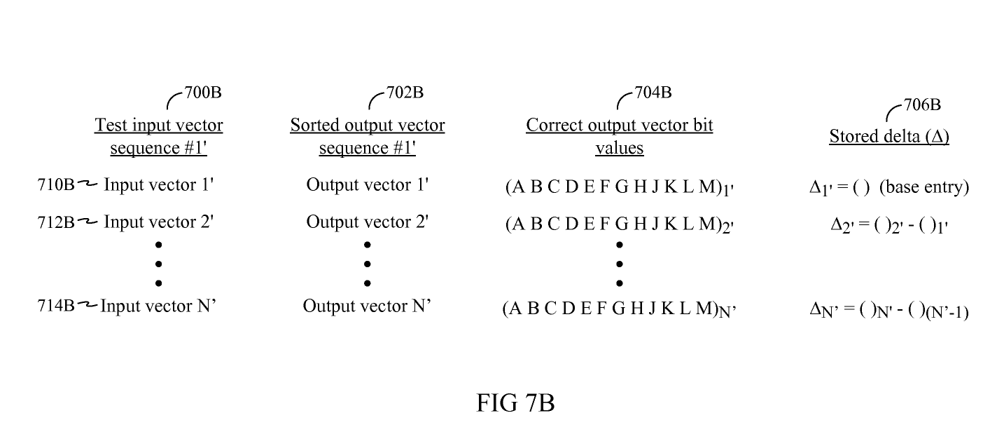

FIG. 7A illustrates an exemplary sequence of test input vectors and un-sorted output vectors, along with corresponding generalized output bit values. In FIG. 7A, column 700A enumerates a first sequence of test input vectors, also denoted as test input vector sequence #1. For example, test input vector sequence #1 includes a first input vector 1 (with 1 being the index of row 710A), a second test vector 2 (with 2 being the index of row 712A), etc., up to an N-th test vector N (with N being the index of row 714A). Column 702A enumerates a sequence of (un-sorted) output vectors, denoted output vector sequence #1, corresponding to the test input vector sequence #1 of column 700A. For example, output vector sequence #1 includes first output vector 1 corresponding to the post-capture cycle output of input vector 1, second output vector 2 corresponding to second input vector 2, etc. Column 704A enumerates the correct output vector bit values corresponding to the output vectors shown in column 702A. For example, (A B C D E F G H J K L M)₁ denotes the twelve bits of output vector 1 arranged from MSB to LSB, (A B C D E F G H J K L M)₂ denotes the twelve bits of output vector 2, etc.

Note in FIG. 7A, the vectors of output vector sequence #1 in column 702A are not necessarily arranged in a monotonic sequence, i.e., the bit value of output vector 1 may be greater or less than the bit value of output vector 2, which may be greater or less than the bit value of output vector 3, etc. According to the sorting technique described herein, the test vectors of test input vector sequence 1 may be re-arranged such that the corresponding output vectors increase (or decrease) monotonically in sequence.

FIG. 7B illustrates an exemplary sequence of test input vectors and sorted output vectors. In FIG. 7B, column 700B enumerates a sequence of test input vectors denoted as test input vector sequence #1′, which includes test input vector 1′ (with 1′ being the index of row 710B), test input vector 2′ (with 2′ being the index of row 712B), etc., up to test input vector N′ (with N′ being the index of row 714B). Column 702B enumerates the output vector sequence #1′, corresponding to the test input vector sequence #1′ of column 700B. As the test input vector sequence #1′ has been pre-sorted, it is expected that the output vectors of output vector sequence #1′ monotonically increases (or decreases) in bit value when the output bits are correct (i.e., no errors). For example, referring to column 704B showing the correct output bit values of the sorted output vector sequence #1′, it is expected that (A B C D E F G H J K L M)_{1′}<. . . <(A B C D E F G H J K L M)_{2′}<(A B C D E F G H J K L M)_{3′}<. . . <(A B C D E F G H J K L M)_{N}′, for the case wherein output vector sequence #1′ is a monotonically increasing sequence.

Once the test vectors are sorted in this manner, the delta (Δ) values, i.e., the difference between consecutive output vectors in the sequence, may be computed and stored in a memory. In particular, the following formula may be used to compute a delta value Δₙ, for an arbitrary output vector n′, wherein n′ denotes the row index in FIG. 7B (Equation 1):

Δ_{n′}=(ABCDEFGHJKLM)_{n′}−(ABCDEFGHJKLM)_{n′-1}.

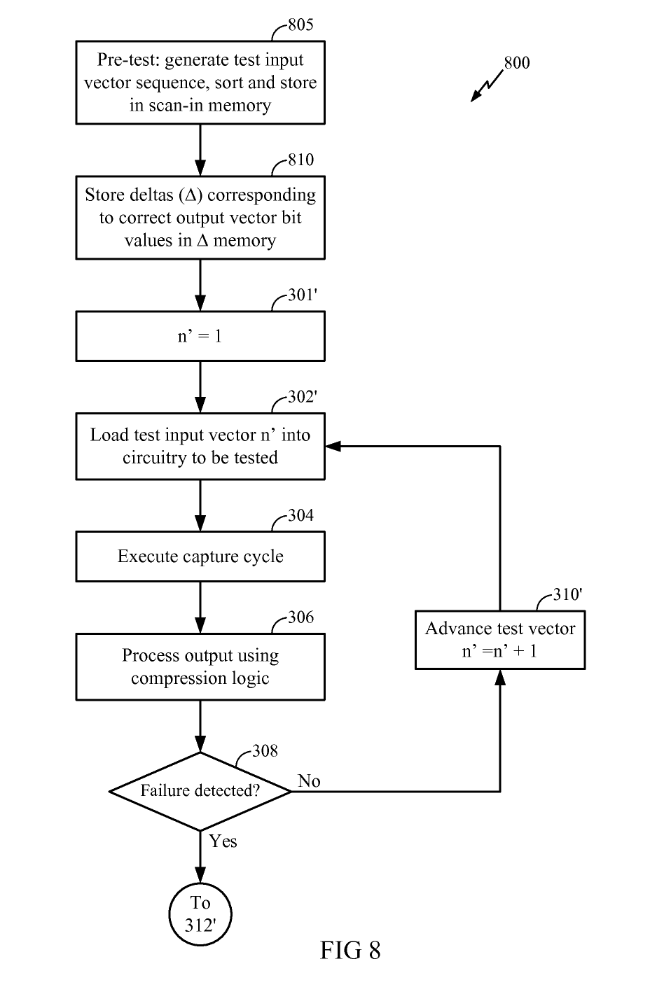

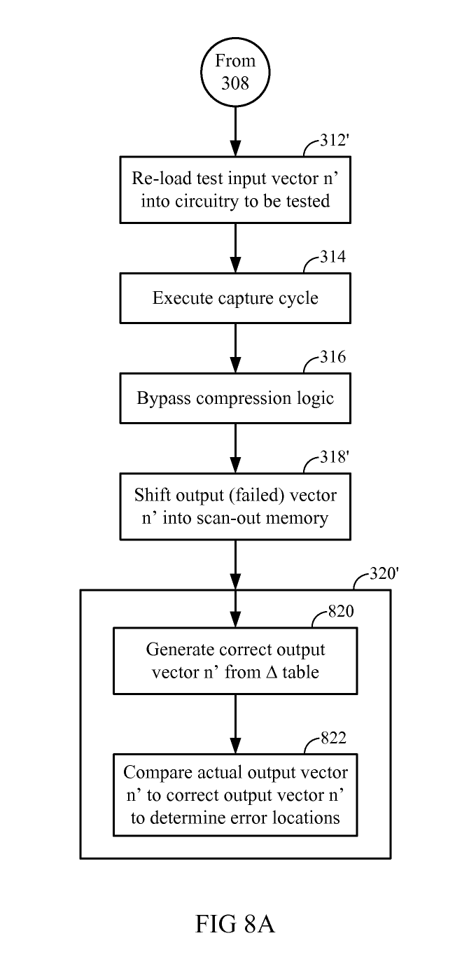

FIG. 8 illustrates an exemplary method 800 for using the sorting technique to identify bit errors in test output vectors according to the present disclosure. Note FIG. 8 is shown for illustrative purposes only, and is not meant to limit the scope of the present disclosure to any particular method disclosed.

In FIG. 8, at block 805, pre-test operations are executed including generating a test input vector sequence and storing said sequence in the scan-in memory. Note the test input vector sequence stored in block 805 will correspond to an input sequence whose output bit values are sorted, e.g., test input vector sequence 1′ in FIG. 7B.

At block 810, the delta values Δ_{n′} corresponding to the input sequence in the scan-in memory are stored in a (possibly separate) memory, also denoted the delta memory. It will be appreciated that the delta values Δ_{n′} may be, e.g., computed according to Equation 1.

The method proceeds to block 301′, wherein an index n′ is initialized to 1.

At block 302′, test input vector n′ is loaded from the scan-in memory into the circuitry to be tested.

Blocks 304-308 proceed similarly as described earlier herein with reference to FIG. 3. Note if a failure is not detected at block 308, the test vector is advanced by incrementing n′ by 1 at block 310′, and the method subsequently returns to block 302′.

If a failure is detected at block 308, the method proceeds to block 312′, wherein the test input vector n′ is re-loaded into the circuitry. Blocks 314-316 proceed similarly as described earlier herein with reference to FIG. 3A.

At block 318′, the actual output vector (for which a failure has been detected) corresponding to test input vector n′ is shifted into the scan-out memory.

Block 320′ performs analysis of the test input vector n′ in the scan-out memory to determine the precise location of the erroneous bit. In particular, at block 820, the correct output bit value for output vector n′ is derived from the delta memory. In an exemplary embodiment, this may be accomplished by calculating a cumulative sum of all entries in the delta memory starting from index l′ (i.e., the base entry) up to n′ to derive the correct output bit value for output vector n′. At block 822, the correct output bit value n′ is compared with actual output vector n′ to determine the locations of any bit errors.

It will be appreciated that by storing the delta values of a sequence according to the sorting technique described hereinabove, considerable memory may be saved as compared to storing the complete output bit values themselves (e.g., all bit values (ABC DEFGHJKLM)ₙ for n=1 to N).

In an alternative exemplary embodiment, a “compression” technique may be used to compress and store the correct output vectors for analysis. According to the compression technique, the correct output vector bits corresponding to a given test input vector sequence are first compressed using a lossless compression technique, and then stored in a memory denoted as a compression memory. When an error is detected in a particular test output vector, the correct output vector as stored in the compression memory is retrieved, decompressed, and compared with the actual output vector to determine the locations of bit errors. This technique may be used in combination with any of the previous or subsequent techniques.

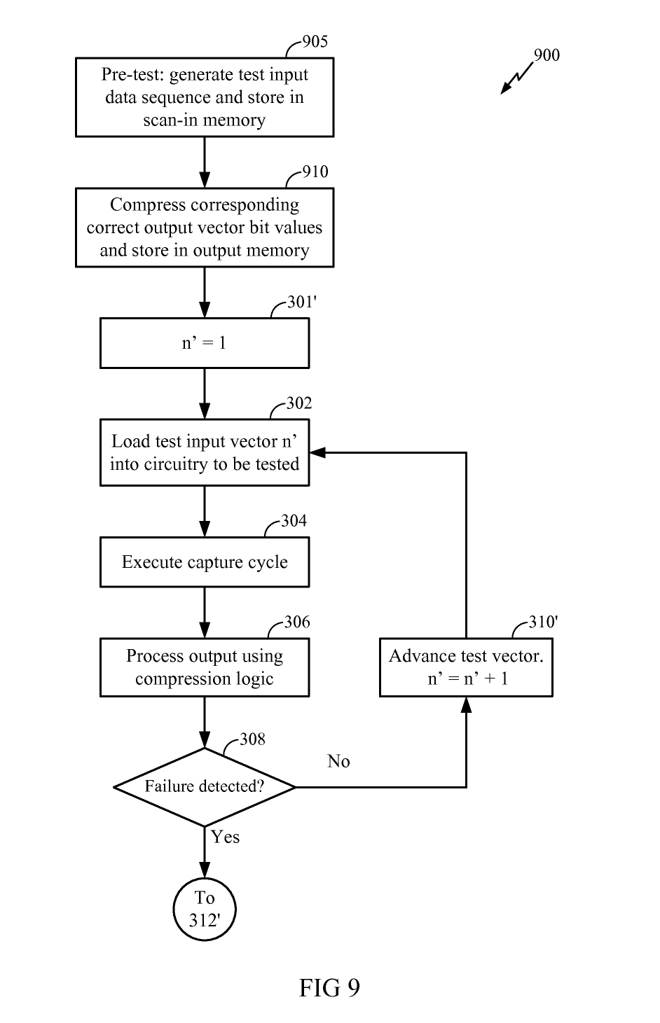

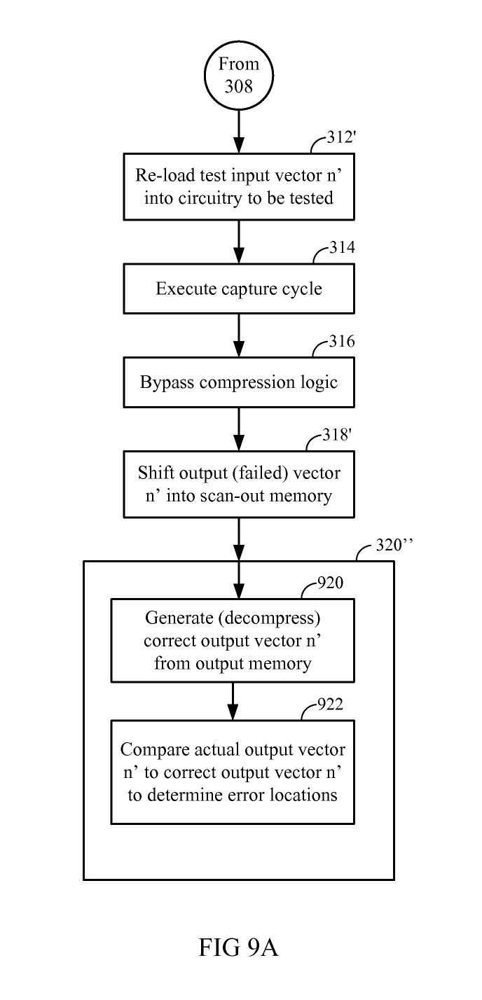

FIGS. 9 and 9A illustrate an exemplary method 900 for implementing the compression technique. Note FIGS. 9 and 9A are shown for illustrative purposes only, and are not meant to limit the scope of the present disclosure to any particular method described. Further note that certain elements in FIGS. 9 and 9A are labeled similarly to elements in FIGS. 8 and 8A illustrating the sorting technique, and it will be appreciated that such similarly labeled elements may correspond to similar functions. It will be appreciated that the sorting technique may in fact be classified as a specific instance of the compression technique, wherein the test vectors are sequenced based on their output states, and the correct output vector bits are compressed by storing only their delta values (as opposed to their full bit values).

In FIG. 9, at block 905, pre-test operations are executed including generating a test input vector sequence and storing said sequence in the scan-in memory.

At block 910, the correct output vectors corresponding to the stored test input vectors are compressed using a data compression technique, as later described hereinbelow. The compressed correct output vectors are stored in a memory denoted the output memory.

Blocks 301′-318′ proceed similarly as described hereinabove with reference to FIGS. 8-8A. At the end of block 318′, the actual output vector n′ containing the one or more errors is shifted into the scan-out memory, and the method proceeds to block 320″ for analyzing the actual output vector n′.

At block 920, the correct output vector n′ is retrieved in compressed form from the output memory and decompressed.

At block 922, the actual output vector n′ is compared to the (decompressed) correct output vector n′ to determine the bits that are in error.

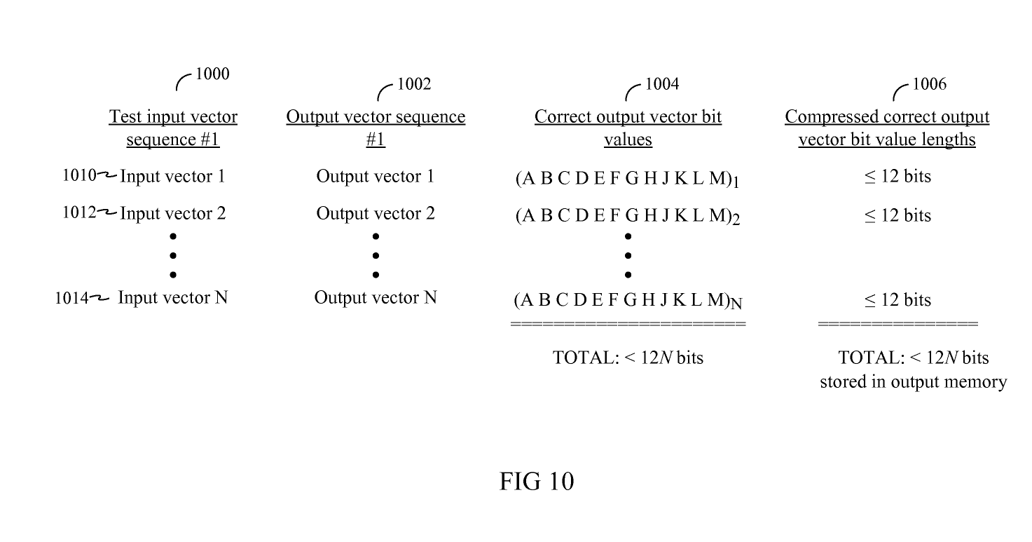

FIG. 10 illustrates an exemplary embodiment of data compression of the correct output vector bits according to the present disclosure. In FIG. 10, column 1000 enumerates a first sequence of test input vector vectors, also denoted as test input vector sequence #1. Test input vector sequence #1 includes a first test input vector 1 at row 1010, a second test input vector 2 at row 1012, etc., up to an N-th test input vector N at row 1014. Column 1002 enumerates a sequence of output vectors, denoted output vector sequence #1, corresponding to the test input vector sequence #1 of column 1000. Column 1004 enumerates the correct output bit values corresponding to the output vectors shown in column 1002. Column 1006 enumerates the lengths of the correct output bit values after compression, corresponding to the correct output bit values in column 1004. For example, the 12-bit output vector 1 in column 1002 may be compressed to a length of less than or equal to 12 bits as indicated in column 1006, and similarly for the rest of the output vector sequence #1 shown, such that the total number of compressed bits corresponding to the correct output bits is less than 12 times N.

One of ordinary skill in the art would appreciate that there a multitude of data compression techniques known in the art, any of which may be applied to compress the correct output bit values for a given output vector sequence. For example, lossless data compression techniques include, but are not limited to, Lempel-Ziv (LZ), DEFLATE, LZW (Lempel-Ziv-Welch), etc. Other encoding techniques include Shannon-Fano coding, Shannon-Fano-Elias coding, Huffman coding, etc. Such techniques are well-known in the art, and their operation will not be further described herein. It will be further appreciated that while the output vectors of an output vector sequence are shown as independently compressed in FIG. 10, in fact a compression technique may jointly encode any or all of the output vectors, and such alternative exemplary embodiments are contemplated to be within the scope of the present disclosure.

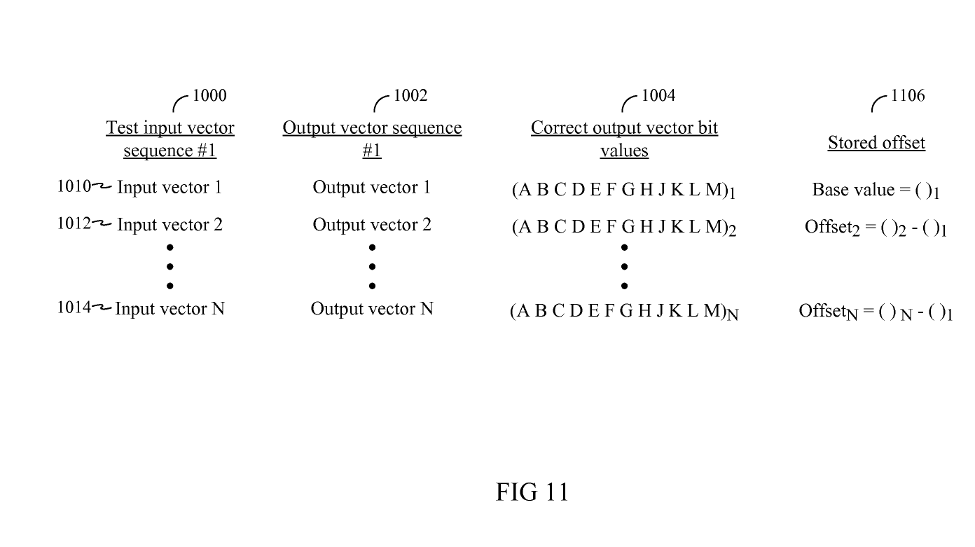

It will be appreciated that other techniques may also be applied to format or otherwise process the correct output vector bits, independently of or in conjunction with the compression techniques described above. For example, FIG. 11 illustrates an “offset” technique according to the present disclosure. In FIG. 11, the test input vector sequence #1 column 1000, output vector sequence 1 column 1002, and the correct bit value column 1004 have been earlier described herein with reference to, e.g., FIG. 10. The stored offset column 1106 enumerates offsets between each output bit value and a base value as follows.

The first entry of the stored offset column 1106 corresponds to the correct output bit value of output vector 1, also denoted herein as the base value. The second entry of column 1106 corresponds to the difference (A B C D E F G H J K L M)₂−(A B C D E F G H J K L M)₁, also denoted as Offset₂. In general, the value of the n-th offset value Offsetₙ corresponds to the difference (A B C D E F G H J K L M)ₙ−(A B C D E F G H J K L M)₁, i.e., the difference between the n-th correct output bit value and the base value.

It will be appreciated that in alternative exemplary embodiments, the base value need not be defined as the correct output bits corresponding to the first test vector in the test input vector sequence. The base value may generally be defined as the correct output bits corresponding to any test vector in the test input sequence, and the offset values for the other entries may be referenced appropriately thereto. Such alternative exemplary embodiments are contemplated to be within the scope of the present disclosure.

It will be appreciated that for certain test vector sequences or configurations of circuitry to be tested, storing the offset values in the input or output memory may require using fewer bits than storing the full output bit values for the entire test sequence. In an exemplary embodiment, the identity of test sequences having such a property may be pre-identified, and the offset technique applied to those sequences. Furthermore, it will be appreciated that the offset technique may be combined with any other of the compression techniques described herein, e.g., Lempel-Ziv, Huffman coding, etc., which encoding techniques may be used to encode the derived offsets shown in column 1106, rather than a full test sequence.

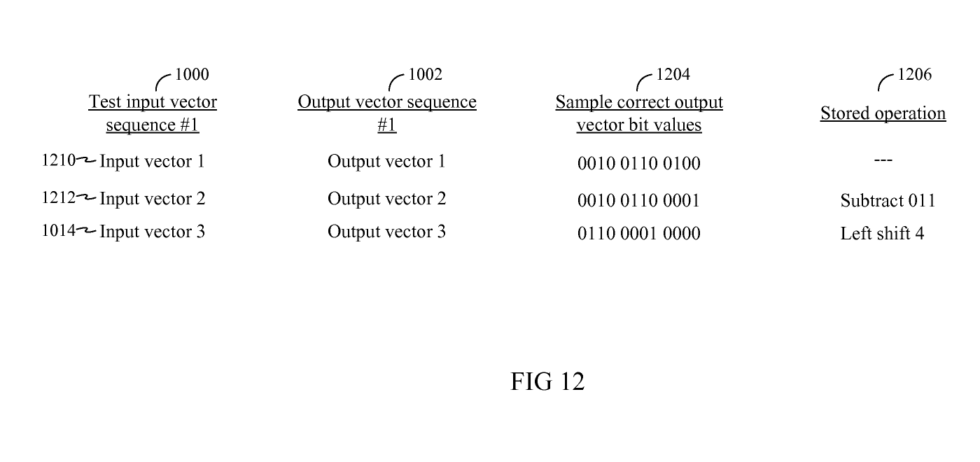

FIG. 12 illustrates a “relative operation” technique according to the present disclosure. In FIG. 12, the test input vector sequence #1 column 1000 and output vector sequence #1 column 1002 have been earlier described herein with reference to, e.g., FIG. 10. The sample correct bit value column 1004 enumerates sample correct output bit values for output vector sequence #1. The sample stored operation column 1206 enumerates operations that may be performed on a designated base value to compute the correct output bit values for another row. Operations are typically selected to minimize tester memory requirements. Multiple operations may be performed on any given vector to obtain the output conditions for the next vector in the sequence.

The first entry of the stored offset column 1206 corresponds to the correct output bit value of output vector 1, also denoted herein as the base value. Alternatively, as earlier described hereinabove, the output vector of any row may generally be designated as the base value. The second entry of column 1206 designates that the correct output bit value corresponding to output vector 2 may be determined by performing the operation of “Subtract 011” relative to the base value (hence the denotation of this technique as the “relative operation” technique). In this case, subtracting 011 from 0010 0110 0100, or the base value, results in 0010 0110 0001 for the correct bit value of output vector 2. The third entry of column 1206 designates that the correct output bit value corresponding to output vector 3 may be determined by performing the operation of “Left shift 4” relative to the base value, resulting in 0110 0001 0000 for the correct bit value of output vector 3.

It will be appreciated that for certain test sequences or configurations of circuitry to be tested, storing the relative operations in the input or output memory may require using fewer bits than storing the full output bit values for the entire test sequence. In an exemplary embodiment, the identity of test sequences having such a property may be pre-identified, and the relative operation technique applied to those sequences. For example, the assignment of the scan order within this technique should be done to minimize the number and type of operations. Furthermore, it will be appreciated that the relative operation technique may be combined with any other of the compression techniques described herein, e.g., Lempel-Ziv, Huffman coding, etc., which encoding techniques may be used to encode the relative operations shown in column 1206, rather than a full test sequence.

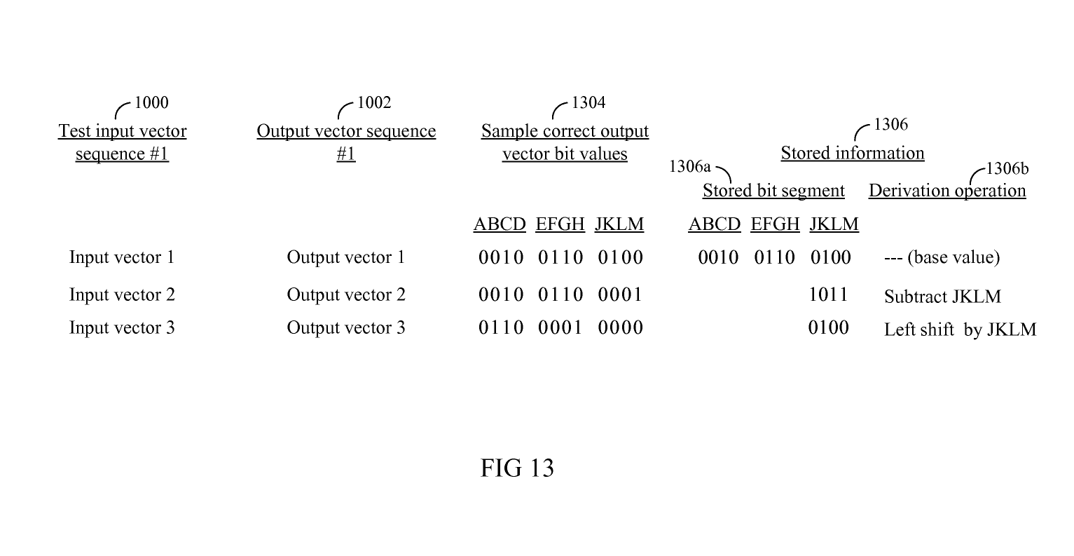

FIG. 13 illustrates a “derivation” technique according to the present disclosure. In FIG. 13, the test input vector sequence #1 column 1000 and output vector sequence #1 column 1002 have been earlier described herein with reference to, e.g., FIG. 10. The sample correct bit value column 1304 enumerates sample correct output bit values for output vector sequence #1. The stored information column 1306 includes a stored bit segment column 1306a storing bit segments corresponding to the correct output bit values, and a derivation operation column 1306b enumerating operations that may be performed to derive one segment of the corresponding correct output vector from another (stored) segment of the correct output vector.

In FIG. 13, the first entry of the stored bit segment column 1306a corresponds to the (complete) correct output bit value of output vector 1, also denoted herein as the base value. Alternatively, as earlier described hereinabove, the output vector of any row may generally be designated as the base value. A corresponding first entry of the derivation operation column 1306b is empty. Alternatively, these may be offset such that the first entry contains the operation required to obtain the second entry, and the last entry is empty.

The second entry of column 1306a contains a bit segment 1011, corresponding to sample JKLM bits of output vector 2 as also illustrated in the second entry of column 1304. The corresponding second entry of column 1306b designates that the remaining segment ABCD EFGH of output vector 2 may be derived by performing a “Subtract JKLM” operation from the ABCD EFGH segment of the base value (hence the denotation of this technique as the “derivation” technique). In particular, subtracting 1011 (i.e., JKLM) from 0010 0110 results in 0001 1010, thus specifying that the correct output bit data for output vector 2 is 0001 1010 1011, as also illustrated in the second entry of column 1304.

The third entry of column 1306a contains a bit segment 0100, corresponding to sample JKLM bits of output vector 3 as also illustrated in the third entry of column 1304. The corresponding third entry of column 1306b designates that the remaining segment ABCD EFGH of output vector 3 may be derived by performing a “Left Shift by JKLM” operation on the ABCD EFGH segment of the base value. In particular, left shifting 0010 0110 by 0100, or 4, results in 0110 0000, thus specifying that the correct output bit data for output vector 3 is 0110 0000 0100, as also illustrated in the third entry of column 1304.

While the derivations are described hereinabove as being performed relative to the base value, it will be appreciated that alternative exemplary embodiments may also be readily implemented, e.g., derivations may be performed relative to a previous vector in the sequence, etc.

It will be appreciated that for certain test sequences or configurations of circuitry to be tested, storing the partial bit segments and derivation operations in the input or output memory as described may require using fewer bits than storing the full output bit values for the entire test sequence. In an exemplary embodiment, the identity of test sequences having such a property may be pre-identified, and the derivation technique applied to those sequences. Furthermore, it will be appreciated that the derivation technique may be combined with any other of the compression techniques described herein, e.g., Lempel-Ziv, Huffman coding, etc., which encoding techniques may be used to encode the information in column 1306, rather than a full test sequence. Furthermore, it will also be appreciated that the values stored in JKLM may be stored in other alternative means, including, but not limited to, storage in the tester program, storage in scan-in memory using extra cycles between tests, unused scan-in memory locations, or don't care scan-in memory locations, or transferred from scan-in memory locations to flip-flops that are unclocked in capture mode (the opposite state of scan enable).

In an alternative exemplary embodiment, a “fixed value” technique may be used to provide information on the identities of erroneous bits. The fixed value technique takes advantage of the fact that, while the size of scan-in memory for storing input test vectors may be allocated in rectangular blocks, e.g., N×12 bits for N test vectors of twelve bits, the flip-flops or registers in the circuitry to be tested is generally not strictly rectangular, as certain flip-flops may be missing from an array if not necessary for circuit operation. In this case, the bit locations in the scan-in memory corresponding to such missing flip-flops will be unused, and thus information relating to the correct output vectors may be “stuffed” in such unused bit locations in scan-in memory and transferred directly (i.e., maintaining their original bit values) to scan-out memory. This technique may be used in combination with any of the other techniques disclosed herein.

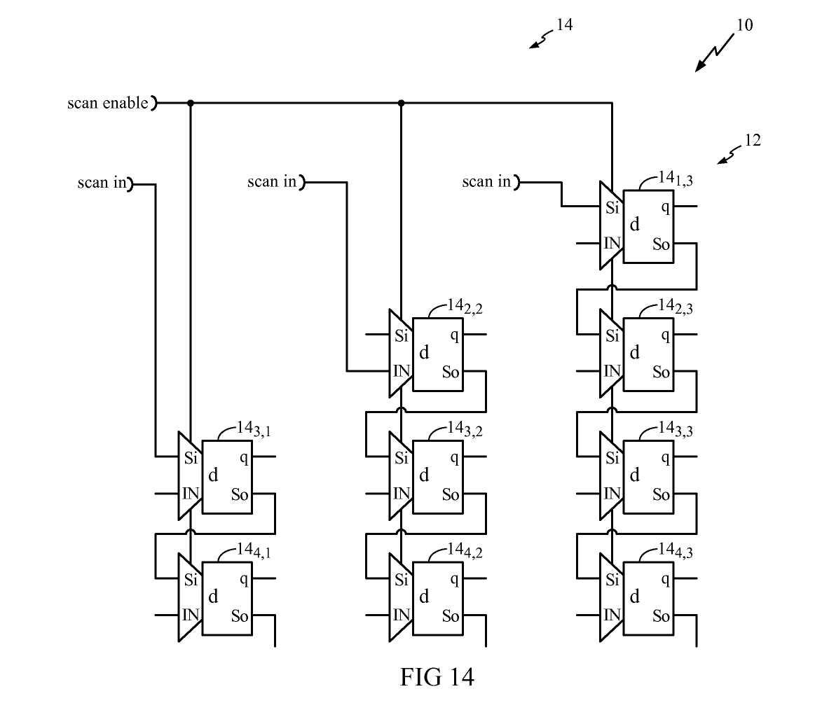

FIG. 14 illustrates an exemplary instance of circuitry to be tested 1410, wherein certain flip-flops are missing from rectangular array. Comparing FIG. 14 to FIG. 2, it will be seen that the flip-flops 14_{1,3}, 14_{2,2}, 14_{2,3}, 14_{3,1}, 14_{3,2}, 14_{3,3}, 14_{4,1}, 14_{4,2}, and 14_{4,3} are present in both figures, while the three flip-flops 14_{1,1}, 14_{1,2}, and 14_{2,1} present in FIG. 2 are missing in FIG. 14.

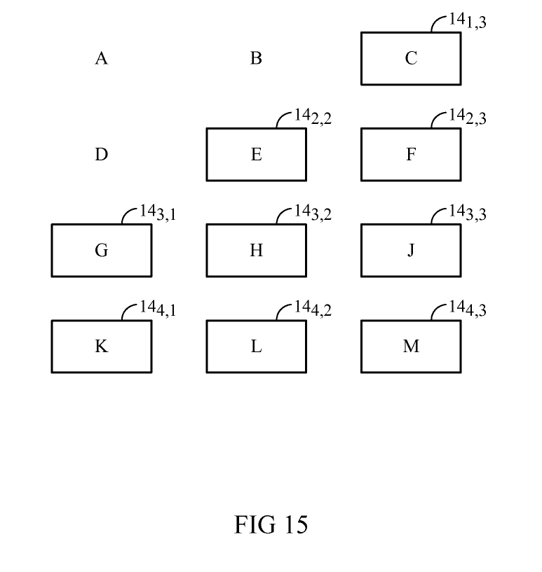

FIG. 15 illustrates an exemplary scheme for labeling the flip-flops shown in FIG. 14. Note FIG. 15 is shown for illustrative purposes only, and is not meant to limit the scope of the present disclosure. In FIG. 15, the labels A, B, and D are assigned to the locations in the array corresponding to the missing flip-flops, while the existing flip-flops are also assigned labels.

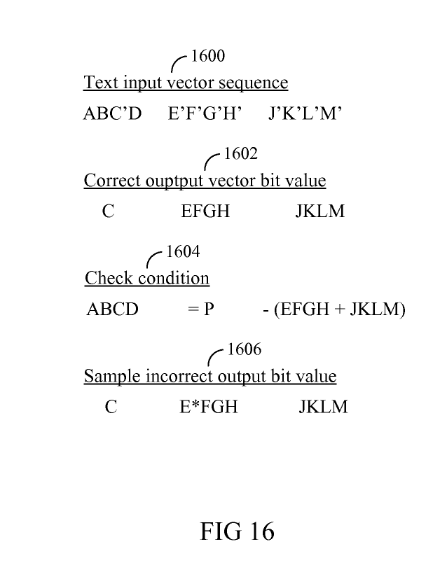

FIG. 16 illustrates a test input vector sequence 1600 (ABC′D E′F′G′H′ J′K′L′M′) stored in the scan-in memory. After the execution cycle, a correct output bit value 1602 corresponding to the test input vector sequence 1600 is shown as (C EFGH JKLM). It will be appreciated that the bits A, B, and D are absent from the correct output bit value 1602, as the corresponding registers were not present in the circuitry. It will further be appreciated that the input bits (C′ E′F′G′H′ J′K′L′M′) are, after operation of the execution cycle, present as bits (C EFGH JKLM) at the output.

The memory locations corresponding to unused registers A, B, and D in the scan-in memory may be used to store certain information for determining the bit value correct output vector. In an exemplary embodiment, the unused registers may store bits, also denoted dummy bits, such that a predesignated mathematical operation performed on the stored dummy bits and the correct output bits (e.g., C EFGH JKLM) produces a known, fixed value. In this case, if the actual output bits contain an error (e.g., C E*FGH JKLM, with E in error as shown in 1606), then performing the predesignated mathematical operation on the stored dummy bits and the actual output bits would produce a value deviating from the fixed value. Furthermore, it will also be appreciated that the values stored in ABD may be stored in other alternative means, including, but not limited to, storage in the tester program, storage in scan-in memory using extra cycles between tests, unused scan-in memory locations, or don't care scan-in memory locations, or transferred from scan-in memory locations to flip-flops that are unclocked in capture mode (e.g., the opposite state of scan enable).

To illustrate an exemplary embodiment of the fixed value technique, an example predesignated mathematical operation is shown at 1604 (labeled “check condition”) as follows (Equation 2):

(ABCD)=P−(EFGH+JKLM);

wherein P represents a known, fixed value. The fixed value may be stored in an external memory (not shown), or it may be stored along with the test input vectors in the scan-in memory, etc. Note Equation 2 is shown for illustrative purposes only, and is not meant to limit the scope of the present disclosure to any particular type of predetermined mathematical operation generating a fixed value. Note that while the example is shown with addition of four bits, any operation on any bitwidth may generally be used, and such alternative exemplary embodiments are contemplated to be within the scope of the present disclosure.

For example, assuming (C EFGH JKLM)=(0 1101 1100) for illustrative purposes, and EFGH+JKLM=0001. If P is chosen to be fixed to 1010, then ABCD=P−(EFGH+JKLM)=1010−0001=1010+1111=0001. In this case, the passing condition, or correct output vector becomes (ABCD EFGH JKLM)=(0001 1101 1100). From knowing the correct output vector, bit locations of errors in output vector may be determined.

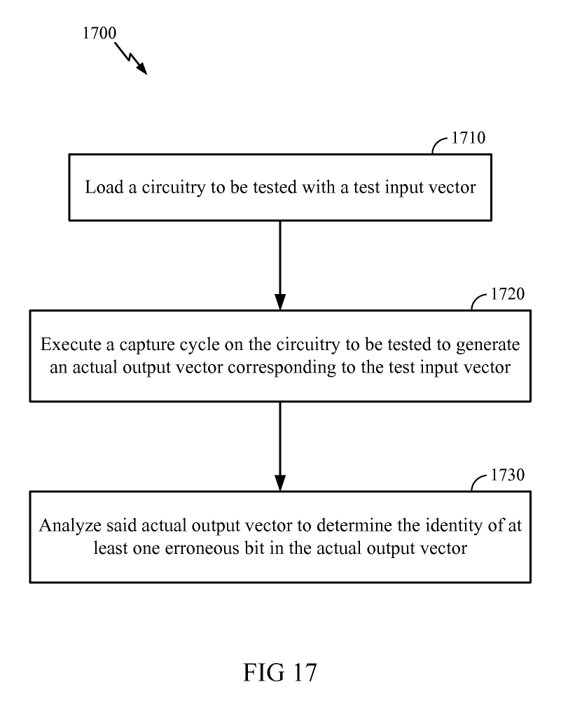

FIG. 17 illustrates an exemplary embodiment of a method 1700 according to the present disclosure. At block 1710, a circuitry to be tested is loaded with a test input vector. At block 1720, a capture cycle is executed on the circuitry to be tested to generate an actual output vector corresponding to the test input vector. At block 1730, said actual output vector is analyzed to determine the identity of at least one erroneous bit in the actual output vector.

In light of the present disclosure, one of ordinary skill in the art will appreciate that any of the techniques described above may practiced independently or in conjunction with each other, and with other techniques not explicitly mentioned herein. For example, in an exemplary embodiment, the sorting may be applied to sequence a set of test input vectors, while compression may be used to compress the deltas stored in the delta table, etc. Such alternative exemplary embodiments are contemplated to be within the scope of the present disclosure.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, VLSI Library elements, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

1. A method comprising:
loading a circuitry to be tested with a test input vector;
executing a capture cycle on the circuitry to be tested to generate an actual output vector corresponding to the test input vector; and
analyzing said actual output vector to determine the identity of at least one erroneous bit in the actual output vector.

2. The method of claim 1, the test input vector associated with a correct output vector, the correct output vector corresponding to a codeword of a forward error-correcting (FEC) code.

3. The method of claim 2, wherein the FEC code is a Hamming code.

4. The method of claim 1, further comprising retrieving from a memory a correct output vector corresponding to the actual output vector, said analyzing comprising comparing said actual output vector to said retrieved correct output vector.

5. The method of claim 4, the test input vector being one in a test input vector sequence.

6. The method of claim 5, the memory storing correct output vectors corresponding to all test input vectors of the test input vector sequence, the correct output vectors being stored in a losslessly compressed form in the memory.

7. The method of claim 5, said memory comprising a delta memory, said retrieving from memory comprising generating the correct output vector by summing a plurality of deltas stored in the delta memory, wherein the test input vectors of the test input vector sequence are ordered such that the output correct output vectors corresponding to the test input vectors are monotonically increasing or decreasing in bit value.

8. The method of claim 1, said retrieving from memory comprising generating the correct output vector by adding an offset value stored in the memory to a base value stored in the memory.

9. The method of claim 1, said retrieving from memory comprising generating the correct output vector by performing a stored operation corresponding to the actual output vector on a base value.

10. The method of claim 1, said retrieving from memory comprising generating the correct output vector by retrieving a segment of the correct output vector from the memory, and performing a stored derivation operation on said segment to derive the correct output vector.

11. The method of claim 1, wherein the number of bits in the actual output vector is less than the number of bits in the corresponding test input vector by an unused number of bits, the loading the circuitry further comprising loading information relating to a correct output vector in the unused number of bits.

12. The method of claim 10, the information relating to the correct output vector comprising bits chosen such that a predetermined mathematical operation performed on the correct output vector bits and the chosen bits results in a predetermined fixed value.

13. An apparatus comprising:
a scan-in memory configured to store a test input vector to be loaded into a circuitry to be tested; and
a scan-out memory configured to store an actual output vector corresponding to the test input vector, the actual output vector generated by the circuitry to be tested after executing a capture cycle on the test input vector; the apparatus configured to analyze the actual output vector stored in the scan-out memory to determine the identity of at least one erroneous bit in the actual output vector.

14. The apparatus of claim 13, the test input vector associated with a correct output vector, the correct output vector corresponding to a codeword of a forward error-correcting (FEC) code.

15. The apparatus of claim 14, wherein the FEC code is a Hamming code.

16. The apparatus of claim 13, further comprising a memory storing a correct output vector corresponding to the actual output vector, the apparatus configured to analyze the actual output vector by comparing said actual output vector to said stored correct output vector.

17. The apparatus of claim 13, the test input vector being one in a test input vector sequence.

18. The apparatus of claim 17, the memory storing correct output vectors corresponding to all test input vectors of the test input vector sequence, the correct output vectors being stored in a losslessly compressed form in the memory.

19. The apparatus of claim 17, said memory comprising a delta memory, the apparatus configured to generate the correct output vector by summing a plurality of deltas stored in the delta memory, wherein the test input vectors of the test input vector sequence are ordered such that the output correct output vectors corresponding to the test input vectors are monotonically increasing or decreasing in bit value.

20. The apparatus of claim 13, said memory storing an offset value corresponding to a correct output vector and a base value.

21. The apparatus of claim 13, said memory storing an operation corresponding to the actual output vector and a base value.

22. The apparatus of claim 13, said memory storing a segment of the correct output vector, and a derivation operation associated with said segment to derive the correct output vector from said segment.

23. The apparatus of claim 13, wherein the number of bits in the actual output vector is less than the number of bits in the corresponding test input vector by an unused number of bits, the scan-in memory storing information relating to a correct output vector in the unused number of bits.

24. The apparatus of claim 23, the information relating to the correct output vector comprising bits chosen such that a predetermined mathematical operation performed on the correct output vector bits and the chosen bits results in a predetermined fixed value.

25. An apparatus comprising:
means for loading a circuitry to be tested with a test input vector; and
means for analyzing an actual output vector of the circuitry to be tested to determine the identity of at least one erroneous bit in the actual output vector.

26. A computer program product storing code for causing a computer to perform tests on a circuitry to be tested, the code comprising:
code for causing a computer to load a circuitry to be tested with a test input vector;
code for causing a computer to execute a capture cycle on the circuitry to be tested to generate an actual output vector corresponding to the test input vector; and
code for causing a computer to analyze said actual output vector to determine the identity of at least one erroneous bit in the actual output vector.
